(19) United States
(12) Patent Application Publication
(10) Pub. No.: US 2024/0339462 A1
(43) Pub. Date: Oct. 10, 2024

(54) ARRAY SUBSTRATE, DISPLAY PANEL, DISPLAY DEVICE, AND TILED DISPLAY APPARATUS

(71) Applicant: BOE TECHNOLOGY GROUP CO., LTD., Beijing (CN)

(72) Inventors: Shuang SUN, Beijing (CN); Fangzhen ZHANG, Beijing (CN); Xinxing WANG, Beijing (CN)

(73) Assignee: BOE TECHNOLOGY GROUP CO., LTD., Beijing (CN)

(21) Appl. No.: 18/294,098

(22) PCT Filed: Jul. 29, 2022
(86) PCT No.: PCT/CN2022/109236

§ 371 Date: Jan. 31, 2024

(51) Int. Cl. H01L 27/12; H01L 25/075; H01L 25/16; H01L 33/10; H01L 33/62

(52) U.S. Cl. CPC H01L 27/1244; H01L 25/0753; H01L 25/167; H01L 33/10; H01L 33/62

(57) ABSTRACT

An array substrate includes: a substrate, a trace layer, a plurality of second electrodes and one or more protective layers. The trace layer is provided on the substrate. The plurality of second electrodes are provided on a side of the substrate away from the trace layer, and the trace layer is electrically connected to the plurality of second electrodes. A protective layer is provided between the substrate and the trace layer, and/or another protective layer is provided between the substrate and the plurality of second electrodes.

### CROSS-REFERENCE TO RELATED APPLICATION

This application is a national phase entry under 35 USC 371 of International Patent Application No. PCT/CN2022/109236 filed on Jul. 29, 2022, which is incorporated herein by reference in its entirety.

### TECHNICAL FIELD

The present disclosure relates to the field of display technologies, and in particular, to an array substrate, a display panel, a display device, and a tiled display apparatus.

### BACKGROUND

Micro light-emitting diode (Micro LED for short) is known as a third generation display technology. Micro LED display devices are difficult to achieve the manufacture of ultra-large-sized products due to technical pressures, such as massive transfer and repair of dead pixels. Therefore, for such products with ultra-large-sized display screens, a superlative scheme at current is to tile small-sized display screens.

### SUMMARY

In an aspect, some embodiments of the present disclosure provide an array substrate. The array substrate includes a substrate, a trace layer, a plurality of second electrodes and one or more protective layers. The trace layer is provided on the substrate. The plurality of second electrodes are provided on a side of the substrate away from the trace layer, and the trace layer is electrically connected to the plurality of second electrodes. A protective layer is provided between the substrate and the trace layer, and/or another protective layer is provided between the substrate and the plurality of second electrodes.

In some embodiments, at least one protective layer includes a reflective layer.

In some embodiments, the reflective layer includes at least two film layers provided in a stack. The reflective layer includes two materials with different refractive indexes, and materials of two adjacent film layers are different.

In some embodiments, the two materials with different refractive indexes include a first material and a second material; a film layer formed by the first material is provided between the substrate and a film layer formed by the second material; and a refractive index of the first material is greater than a refractive index of the second material.

In some embodiments, the two materials with different refractive indexes include a first material and a second material; the first material forms at least one first film layer, the second material forms at least one second film layer, and the at least one first film layer are alternately arranged with the at least one second film layer; and in the reflective layer, a film layer closest to the substrate is a first film layer; and a refractive index of the first material is greater than a refractive index of the second material.

In some embodiments, the two materials with different refractive indexes include a first material; and a product of a thickness of a film layer formed by the first material and a refractive index of the first material is ¼ times a wavelength of light to be reflected by the reflective layer.

In some embodiments, the two materials with different refractive indexes include a second material; and a product of a thickness of a film layer formed by the second material and a refractive index of the second material is ¼ times a wavelength of light to be reflected by the reflective layer.

In some embodiments, the two materials with different refractive indexes include a first material, the first material is titanium dioxide, and a film layer formed by the first material is provided on the substrate.

In some embodiments, the film layer formed by the first material is located between the substrate and a film layer formed by the second material.

In some embodiments, the second material is silicon dioxide.

In some embodiments, at least one protective layer includes an energy absorbing layer.

In some embodiments, the energy absorbing layer has a band gap less than 3.5 eV.

In some embodiments, a material of the energy absorbing layer is titanium dioxide.

In some embodiments, the trace layer includes a plurality of connection traces, and the plurality of connection traces are electrically connected to the plurality of second electrodes; and an orthographic projection of the plurality of connection traces on the substrate is located within an orthographic projection of at least one protective layer on the substrate.

In some embodiments, the trace layer includes a driving circuit layer, and the driving circuit layer includes: an active layer and a gate layer. The active layer is provided on the substrate or the protective layer provided between the substrate and the trace layer; and the gate layer is provided on a side of the active layer away from the substrate. An orthographic projection of the active layer on the substrate is located within an orthographic projection of at least one protective layer on the substrate.

In some embodiments, the protective layer provided between the substrate and the trace layer includes an energy absorbing layer, and the another protective layer provided between the substrate and the plurality of second electrodes includes a reflective layer; alternatively, the protective layer provided between the substrate and the trace layer includes a reflective layer, and the another protective layer provided between the substrate and the plurality of second electrodes includes an energy absorbing layer.

In another aspect, some embodiments of the present disclosure provide a display panel. The display panel includes: the array substrate according to any one of the above embodiments, and a plurality of light-emitting devices. The array substrate further includes a driving circuit layer provided on the substrate; and the plurality of light-emitting devices are arranged in an array on a side of the driving circuit layer away from the substrate.

In yet another aspect, some embodiments of the present disclosure provide a display device. The display device includes: the display panel according to any one of the above embodiments, a flexible circuit board and a driving circuit board. The driving circuit board is provided on a side of the substrate away from the trace layer, and the driving circuit board is electrically connected to the trace layer through the flexible circuit board.

In yet another aspect, some embodiments of the present disclosure provide a tiled display apparatus. The tiled display apparatus includes a plurality of display devices each according to any one of the above embodiments, and the plurality of display devices are tiled together.

### BRIEF DESCRIPTION OF THE DRAWINGS

In order to describe technical solutions in the present disclosure more clearly, the accompanying drawings to be used in some embodiments of the present disclosure will be introduced briefly; obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display device, in accordance with some embodiments of the present disclosure;

FIG. 2 is a front structural diagram of a display device, in accordance with some embodiments of the present disclosure;

FIG. 3 is a back structural diagram of a display device, in accordance with some embodiments of the present disclosure;

FIG. 4 is a structural diagram of a display panel, in accordance with some embodiments of the present disclosure;

FIG. 5 is a front structural diagram of a display panel, in accordance with some embodiments of the present disclosure;

FIG. 6 is a structural diagram of a light region and a driving chip of a display panel, in accordance with some embodiments of the present disclosure;

FIG. 7 is a structural diagram of another display panel, in accordance with some embodiments of the present disclosure;

FIG. 8 is a structural diagram of a first type of display panel having a protective layer, in accordance with some embodiments of the present disclosure;

FIG. 9 is a structural diagram of a second type of display panel having a protective layer, in accordance with some embodiments of the present disclosure;

FIG. 10 is a structural diagram of a third type of display panel having a protective layer, in accordance with some embodiments of the present disclosure;

FIG. 11 is a structural diagram of a fourth type of display panel having a protective layer, in accordance with some embodiments of the present disclosure;

FIG. 12 is a structural diagram of a first type of display panel having a reflective layer, in accordance with some embodiments of the present disclosure;

FIG. 13 is a structural diagram of a second type of display panel having a reflective layer, in accordance with some embodiments of the present disclosure;

FIG. 14 is a structural diagram of a third type of display panel having a reflective layer, in accordance with some embodiments of the present disclosure;

FIG. 15 is a structural diagram of a reflective layer, in accordance with some embodiments of the present disclosure;

FIG. 16 is a structural diagram of a fourth type of display panel having a reflective layer, in accordance with some embodiments of the present disclosure;

FIG. 17 is a structural diagram of a fifth type of display panel having a reflective layer, in accordance with some embodiments of the present disclosure;

FIG. 18 is a structural diagram of a sixth type of display panel having a reflective layer, in accordance with some embodiments of the present disclosure;

FIG. 19 is a structural diagram of a seventh type of display panel having a reflective layer, in accordance with some embodiments of the present disclosure;

FIG. 20 is a structural diagram of a first type of display panel having an energy absorbing layer, in accordance with some embodiments of the present disclosure;

FIG. 21 is a structural diagram of a second type of display panel having an energy absorbing layer, in accordance with some embodiments of the present disclosure;

FIG. 22 is a structural diagram of a third type of display panel having an energy absorbing layer, in accordance with some embodiments of the present disclosure;

FIG. 23 is a structural diagram of a first type of display panel having an energy absorbing layer and a reflective layer, in accordance with some embodiments of the present disclosure;

FIG. 24 is a structural diagram of a second type of display panel having an energy absorbing layer and a reflective layer, in accordance with some embodiments of the present disclosure;

FIG. 25 is a structural diagram of a third type of display panel having an energy absorbing layer and a reflective layer, in accordance with some embodiments of the present disclosure;

FIG. 26 is a structural diagram of a fourth type of display panel having an energy absorbing layer and a reflective layer, in accordance with some embodiments of the present disclosure;

FIG. 27 is a structural diagram of a fifth type of display panel having an energy absorbing layer and a reflective layer, in accordance with some embodiments of the present disclosure;

FIG. 28 is a structural diagram of a sixth type of display panel having an energy absorbing layer and a reflective layer, in accordance with some embodiments of the present disclosure; and

FIG. 29 is a structural diagram of a tileable display apparatus, in accordance with some embodiments of the present disclosure.

### DETAILED DESCRIPTION

The technical solutions in embodiments of the present disclosure will be described clearly and completely with reference to the accompanying drawings; obviously, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment,” “some embodiments,” “exemplary embodiments,” “example,” “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, the features defined with “first” and “second” may explicitly or implicitly include one or more of the features. In the description of the embodiments of the present disclosure, the term “a plurality of/the plurality of” means two or more unless otherwise specified.

Some embodiments may be described using the terms “coupled,” “connected” and their derivatives. For example, the term “connected” may be used in the description of some embodiments to indicate that two or more components are in direct physical or electrical contact with each other. As another example, the term “coupled” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C,” both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

As used herein, the term “if” is, optionally, construed as “when” or “in a case where” or “in response to determining that” or “in response to detecting,” depending on the context. Similarly, depending on the context, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event].”

The use of the phrase “applicable to” or “configured to” herein means an open and inclusive expression, which does not exclude devices that are applicable to or configured to perform additional tasks or steps.

In addition, the phase “based on” used is meant to be open and inclusive, since a process, step, calculation or other action that is “based on” one or more of the stated conditions or values may, in practice, be based on additional conditions or value exceeding those stated.

The term “about,” “substantially,” and “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

Exemplary embodiments are described herein with reference to section views and/or plan views as idealized exemplary drawings. In the accompanying drawings, thicknesses of layers and sizes of regions are enlarged for clarity. Variations in shapes with respect to the accompanying drawings due to, for example, manufacturing technologies and/or tolerances may be envisaged. Therefore, the exemplary embodiments should not be construed as being limited to the shapes of the regions shown herein, but including deviations due to, for example, manufacturing. For example, an etched region shown as a rectangle shape generally has a curved feature. Therefore, the regions shown in the accompanying drawings are schematic in nature, and their shapes are not intended to show actual shapes of regions in a device, and are not intended to limit the scope of the exemplary embodiments.

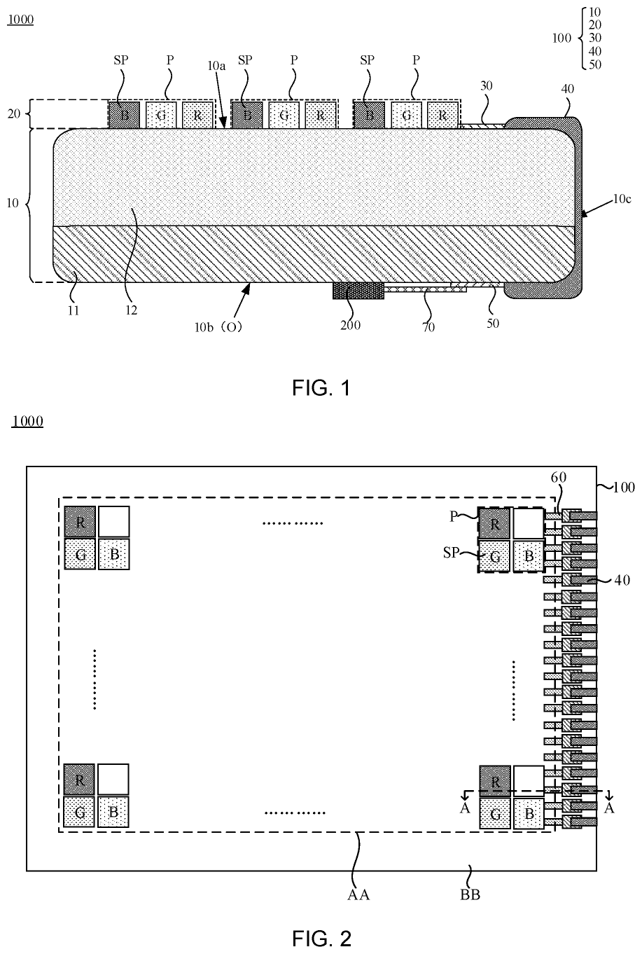

Some embodiments of the present disclosure provide a display device. As shown in FIG. 1, the display device 1000 includes a display panel 100 and a driving circuit board 200. The driving circuit board 200 may be provided on a side of a non-display surface O of the display panel 100. The driving circuit board 200 is configured as a driving integrated circuit (IC) that drives the display panel 100 to display images. The driving circuit board 200 includes, for example, a gate driving circuit, a source driving circuit, a timing controller, a power supply circuit, etc. The driving circuit board 200 is electrically connected to the display panel 100 and is configured to output corresponding signals to control the display panel 100 to display images.

In some embodiments, as shown in FIG. 2, the display panel 100 includes a display area AA and a peripheral area BB provided at least on one side of the display area AA. For example, the peripheral area BB may be located on one side, two sides, or three sides of the display area AA; alternatively, the peripheral areas BB may be provided around the display area AA. The display area AA is provided therein with a plurality of pixels P arranged in an array and a plurality of signal lines 60, and the plurality of signal lines 60 are electrically connected to the plurality of pixels P. Each pixel P includes multiple sub-pixels SP. The sub-pixel SP is the smallest unit of the display panel 100 for image display. Each sub-pixel SP can display a single color, such as red (R), green (G) or blue (B). The brightness (gray scale) of sub-pixels SP of different colors can be adjusted, so a plurality of colors can be displayed through combination and superposition of colors, thereby achieving a full-color display of the display panel 100. Each sub-pixel SP includes at least one light-emitting device, and the light-emitting device may be an inorganic light-emitting diode. For example, the light-emitting devices may be sub-millimeter light-emitting diodes (mini light-emitting diodes, Mini LEDs) and/or micro light-emitting diodes (micro light-emitting diodes, Micro LEDs). Among them, the sub-millimeter light-emitting diode has a size greater than or equal to 100 μm and less than 500 μm, and the microlight-emitting diode has a size less than 100 μm.

In some examples, each pixel P receives electrical signals transmitted by corresponding signal lines 60 to emit light. Under the control of different electrical signals, the pixel P generate different brightnesses (gray scales), so that all pixels P of the display panel 100 generate an image.

During the display process of the display panel 100, the plurality of pixels P are scanned line by line and are provided with a set of data signals by corresponding signal lines 60, so that the display panel 100 displays an image under the control of the data signals. After being scanned line by line again, the plurality of pixels P receive a new set of data signals provided by the signal lines 60 electrically connected thereto, and the display panel 100 displays a new image, thereby refreshing the display image. As a result, a successive plurality of display images are refreshed one by one to form a display video.

In some embodiments, the light-emitting devices adopt sub-millimeter light-emitting diodes and/or micro light-emitting diodes. Under the pressure of existing process capabilities and cost factors, large-sized display panels are difficult to be directly manufactured. The current scheme is to use a manner in which multiple small-sized display panels tiled together to achieve a large size. As shown in FIG. 1, the driving circuit board 200 of the display device 1000 is bonded to the side of the non-display surface O of the display panel, which may reduce a width of the peripheral area and facilitate the tiling of display panels 100 into a large-sized display apparatus.

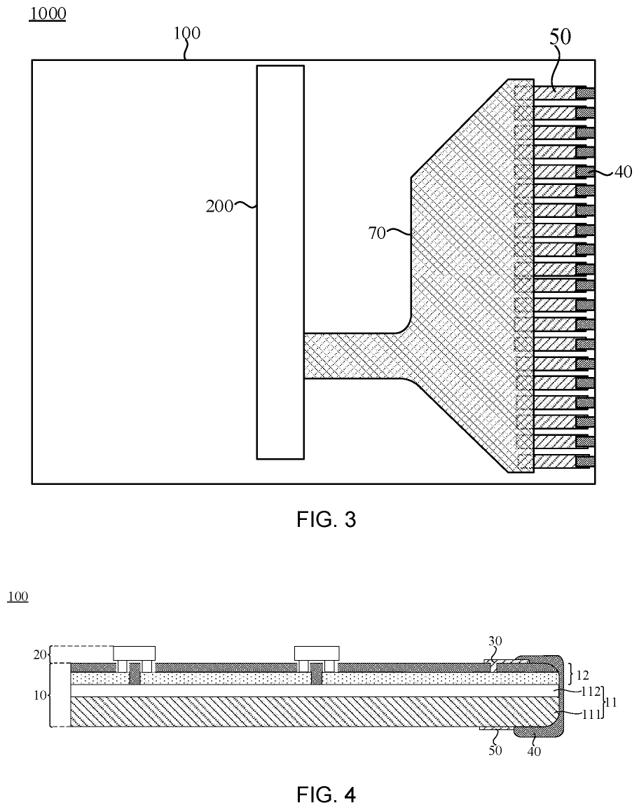

FIG. 1 is a cross-sectional view taken along the A-A direction in FIG. 2, FIG. 2 is a structural diagram of the side of the display surface of the display device 1000, and FIG. 3 is a structural diagram of the side of the non-display surface O of the display device 1000. In some embodiments, as shown in FIG. 1, FIG. 2 and FIG. 3, the display panel 100 includes an array substrate 10, a light-emitting device layer 20, a plurality of first electrodes 30, a plurality of side traces 40 and a plurality of second electrodes 50. The array substrate 10 includes a first surface 10a, a second surface 10b opposite the first surface 10a, and multiple side surfaces 10c connecting the first surface 10a and the second surface 10b. The second surface 10b of the array substrate 10 is also the side of the non-display surface O of the display device.

One of the multiple side surfaces 10c serves as a selected side surface. The light-emitting device layer 20 and the plurality of first electrodes 30 are provided on the first surface 10a of the array substrate 10, in which the plurality of first electrodes 30 are proximate to the selected side surface. The plurality of side traces 40 include some traces provided on the first surface 10a, some traces provided on the selected side surface and some traces provided on the second surface 10b. The driving circuit board 200 and the plurality of second electrodes 50 are provided on the second surface 10b of the array substrate 10, in which the plurality of second electrodes 50 are proximate to selected side surface. The plurality of first electrodes 30 are electrically connected to the light-emitting device layer 20 and corresponding side traces 40. The plurality of second electrodes 50 are electrically connected to the driving circuit board 200/flexible circuit board (flexible printed circuit board, FPC board) 70 and corresponding side traces 40, in which the flexible circuit board 70 can electrically connect the second electrodes 50 and the driving circuit board 200. In this way, the driving circuit board 200 is electrically connected to the second electrodes 50, the side traces 40 and the first electrodes 30 in sequence, thereby transmitting electrical signals to the light-emitting device layer 20.

In some embodiments, the first electrodes 30 located on the first surface 10a of the array substrate 10 and the second electrodes 50 located on the second surface 10b of the array substrate 10 are formed by electroplating, vapor deposition, pad printing silver paste or wet etching. For the side traces 40, a metal plating layer may be formed on the first surface 10a, the selected side surface and the second surface 10b of the array substrate 10, and then the metal plating layer is etched using a laser light to be patterned, so as to obtain the plurality of side traces.

In some embodiments, as shown in FIG. 4 and FIG. 7, the array substrate 10 includes a base 11 and a trace layer provided on the base 11. The base 11 may include a substrate 111 and a buffer layer (Buffer) 112. The substrate 111 may be a silicon substrate, the buffer layer 112 is provided on the substrate 111, and the trace layer 12 is provided on a side of the buffer layer 112 away from the substrate 111.

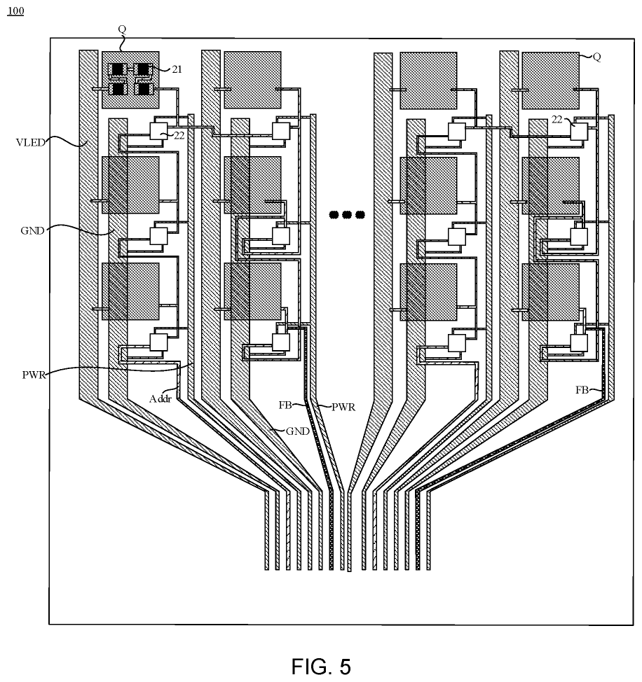

In some embodiments, as shown in conjunction with FIG. 4 and FIG. 5, the trace layer 12 may include a plurality of connection traces, and the light-emitting device layer 20 may include a plurality of light-emitting devices 21 and a plurality of driving chips 22 which are arranged in an array. The array substrate includes a plurality of light regions Q arranged in an array. Each light region Q is provided therein with some series and/or parallel light-emitting devices 21 and is provided with at least one driving chip 22 corresponding thereto. Some series and/or parallel light-emitting devices 21 located in a light region Q are electrically connected to a driving chip 22 corresponding to the same light region Q.

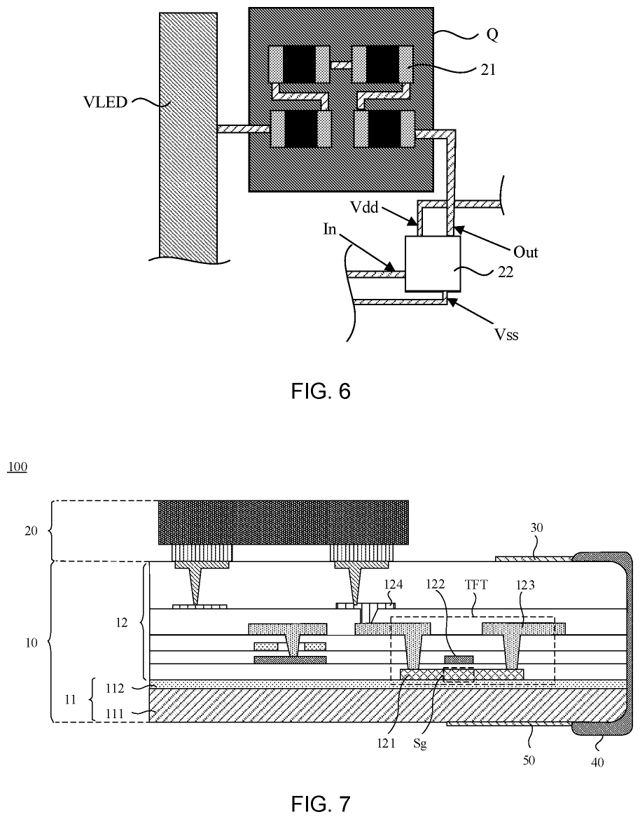

In some examples, the plurality of connection traces include first power supply voltage signal lines VLED, second power supply voltage signal lines PWR, third power supply voltage signal lines GND, addressing signal lines Addr, and feedback signal lines FB. Each light region Q may include multiple light-emitting devices 21, for example, the number of the light-emitting devices may be four, six or eight. Exemplarily, a light region Q includes four light-emitting devices 21 connected in series, in which a first end of the series-connected light-emitting devices 21 is electrically connected to a first power supply voltage signal line VLED, and a second end of the series-connected light-emitting devices 21 is electrically connected to a driving chip 22 corresponding to the same light region Q. In some examples, as shown in FIG. 6, each driving chip 22 may include four pins: a signal input pin In, an output pin Out, a first power supply pin Vdd, and a second power supply pin Vss. The first power supply pin Vdd of each driving chip 22 is electrically coupled to a second power supply voltage signal line PWR, and the second power supply voltage signal line PWR is configured to transmit a second level signal to the driving chip 22. For example, the second level signal may be a high level signal. The second power supply pin Vss of each driving chip 22 is electrically connected to a third power supply voltage signal line GND, and the third power supply voltage signal line GND is configured to transmit a first level signal to the driving chip 22. For example, the first level signal may be a low level signal.

Driving chips 22 corresponding to some light regions Q may be cascaded. In the cascaded driving chips 22, an output pin Out of an upper-level driving chip 22 is electrically connected to a signal input pin In of a lower-level driving chip 22. And, a signal input pin In of the first driving chip 22 in the cascaded driving chips 22 is electrically connected to an addressing signal line Addr, and the addressing signal line Addr is configured to transmit an addressing signal to the first driving chip 22; and an output pin Out of the last driving chip 22 in the cascaded driving chips 22 is electrically connected to a feedback signal line FB, and the feedback signal line FB is configured to transmit a feedback signal.

In some embodiments, when the laser light etches some side traces on the second surface, there may exist a situation in which the laser light penetrates through the substrate, and is incident to the trace layer, so the residual energy of the laser light may cause some of the connection traces to be broken, which may cause some of the light regions of the display panel to fail to emit light normally.

In some other embodiments, as shown in FIG. 7, the trace layer 12 may include a driving circuit layer, and the driving circuit layer includes functional layers and insulation layers each located between adjacent functional layers. The functional layers may include an active layer 121, a gate layer 122, a first source-drain metal layer 123, a second source-drain metal layer 124, etc., in which the active layer 121, the gate layer 122 and the first source-drain metal layer 123 are used to form a plurality of pixel driving circuits of the display panel 100. The light-emitting device layer 20 is provided on a side of the driving circuit layer away from the base 11, and the light-emitting devices located in the light-emitting device layer 20 are electrically connected to corresponding pixel driving circuits.

The pixel driving circuit may include multiple transistors and a capacitor. Exemplarily, the transistor may be a field effect transistor or other switching devices with the same properties, in which the field effect transistor may be a thin film transistor (TFT), such as an oxide thin film transistor, and the embodiments of the present disclosure are described by taking an example of the thin film transistors.

The active layer 121 may be made of polycrystalline silicon (P-Si), and the active layer 121 includes active layer patterns of the transistors. The gate layer 122 includes a plurality of gate lines, and each gate line passes through active layer patterns of corresponding transistors. A portion, overlapping with the gate line, of an active layer pattern of a transistor is a channel region Sg of the transistor, and a portion, overlapping with the active layer pattern of the transistor, of the gate line is a gate terminal of the transistor. Insulation layers located below the first source-drain metal layer 123 are provided therein with a plurality of via holes. Portions, located on both sides of the channel region Sg, of the active layer pattern of the transistor are electrically connected to traces and/or connection terminals located in the first source-drain metal layer 123 through via holes, and the traces and/or connection terminals located in the first source-drain metal layer 123 that are electrically connected to the portions of the active layer pattern of the transistor on both sides of the channel region Sg may be a source or drain of the transistor. That is to say, an active layer pattern, a portion of a gate line overlapping the active layer pattern, the traces and/or connection terminals in the first source-drain metal layer 123 that are electrically connected to the active layer pattern may form a thin film transistor TFT.

It will be noted that “one passing through another” in the embodiments of the present disclosure means that an orthographic projection of the former on the base overlaps with an orthographic projection of the latter on the base. For example, a gate line passes through active layer patterns of corresponding transistors, which means that an orthographic projection of the gate line located in the gate layer on the base may overlap with orthographic projections of the active layer patterns of the multiple transistors on the base.

In some examples, a connection terminal located in the first source-drain metal layer may serve as a signal output terminal of the pixel driving circuit. That is, the connection terminal of the first source-drain metal layer can receive a driving signal provided by the pixel driving circuit. A connection terminal located in the second source-drain metal layer can be electrically connected to the connection terminal located in the first source-drain metal layer through a via hole penetrating through an insulation layer. The connection terminal located in the second source-drain metal layer may serve as an anode electrode of a light-emitting device. The first source-drain metal layer or the second source-drain metal layer may include a cathode trace, and a cathode of the light-emitting device is electrically connected to the cathode trace through a via hole penetrating through the first source-drain metal layer or the second source-drain metal layer.

In some embodiments, when the laser light etches some side traces on the second surface, there may exist a situation in which the laser light penetrates through the base, and is incident to the active layer. After the polycrystalline silicon in the active layer absorbs the energy, it may cause a serious deterioration in the characteristics of the thin film transistor, such as a shift in the threshold voltage and/or an increase in the leakage current. As a result, the pixel driving circuit is difficult to accurately control the magnitude of the voltage or current of the output driving signal, which in turn results in inaccurate brightness of the light-emitting device, thereby causing the presence of a color deviation, uneven brightness, and so forth, in the image formed on the display panel.

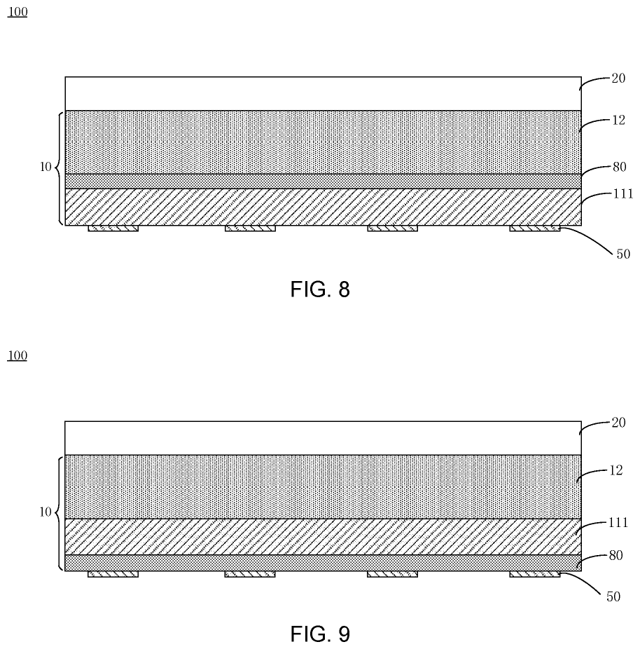

In light of this, in an aspect, some embodiments of the present disclosure provide an array substrate. As shown in FIG. 8 to FIG. 10, the array substrate 10 includes: a substrate 111, a trace layer 12, a plurality of second electrodes 50 and a protective layer 80. Among them, the substrate 111, the trace layer 12 and the plurality of second electrodes 50 are consistent with the substrate 111, the trace layer and the second electrodes mentioned in the display panel of the above embodiment in terms of structure, function and arrangement position, and details will not be repeated here. The protective layer 80 is provided between the substrate 111 and the trace layer 12 and/or between the substrate 111 and the plurality of second electrodes 50, in which the protective layer 80 is configured to absorb or reflect the laser light.

In some examples, as shown in FIG. 8, a protective layer 80 is provided between the substrate 111 and the trace layer 12.

In some other examples, as shown in FIG. 9, a protective layer 80 is provided between the substrate 111 and the plurality of second electrodes 50.

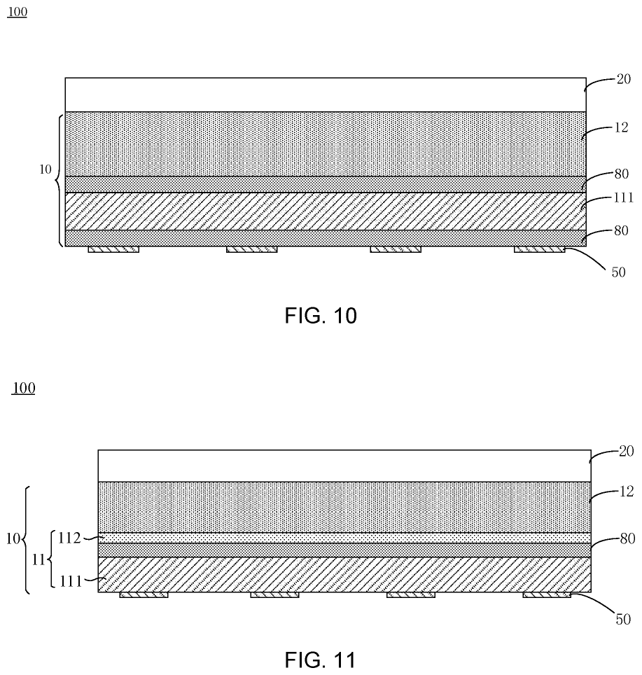

In yet some other examples, as shown in FIG. 10, the substrate 111 and the trace layer 12, and the substrate 111 and the plurality of second electrodes 50 are both provided therebetween with a protective layer 80.

When the plurality of second electrodes 50 are processed by a laser light etching process, a portion of the laser light will penetrate through the substrate 111 and is incident to the protective layer 80. The protective layer 80 can absorb or reflect the laser light, so that the laser light cannot be directly incident to the trace layer 12. That is to say, the laser light will not cause damage to the connection traces or the active layer in the trace layer 12, which improves the product yield of the display panel.

In some embodiments, the array substrate 10 further includes a buffer layer 112, and the buffer layer 112 is provided on a side of the substrate proximate to the trace layer 12. A protective layer 80 is provided between the substrate 111 and the buffer layer 112.

In some examples, the array substrate 10 includes a base. The base includes the substrate 111 and the buffer layer 112 provided on the substrate 111. The trace layer 12 is provided on a side of the buffer layer 112 away from the substrate 111. In a case where a protective layer 80 is provided on a side of the substrate 111 proximate to the trace layer 12, the protective layer 80 is located between the substrate 111 and the buffer layer 112.

In some embodiments, an orthographic projection of a plurality of connection traces on the substrate 111 is located within an orthographic projection of the protective layer 80 on the substrate 111.

In some examples, when performing the etching process on a metal plating layer located on the second surface, the laser light is vertically incident to the metal plating layer. In order to prevent a portion of the laser light from penetrating through the substrate 111 and causing damage to the trace layer 12, the protective layer 80 should completely isolate the laser light from the trace layer 12 in a direction parallel to the second surface, realizing that the laser light will not be incident to the trace layer 12, and avoiding the laser light from causing damage to the trace layer 12.

Exemplarily, the trace layer includes the plurality of connection traces. When performing the etching process on the metal plating layer, the laser light may run through a gap between two side traces, and penetrate through the substrate 111, and then is incident to a connection trace of the plurality of connection traces. As a result, the energy of the laser light may cause the connection trace to be broken. The breakage of the connection trace may cause problems, such as some of the light regions of the display panel failing to emit light normally.

The protective layer 80 completely covers the plurality of connection traces, which may prevent the laser light from being incident to the connection traces, prevent the connection traces from being disconnected due to the laser light, and improve the product yield.

Exemplarily, the trace layer includes the driving circuit layer. When performing the etching process on the metal plating layer, the laser light is vertically incident to the trace layer, and a portion of the active layer may be irradiated by the laser light. The characteristics of some thin film transistors will be severely deteriorated under the action of the energy of the laser light, such as a shift in the threshold voltage and/or an increase in the leakage current. In order to avoid the laser light damage to the driving circuit layer, the protective layer should completely cover the active layer in the direction parallel to the second surface, so that the laser light will not cause changes to the characteristics of the portion of the active layer, the image quality of the display panel is stable, and the product yield is high.

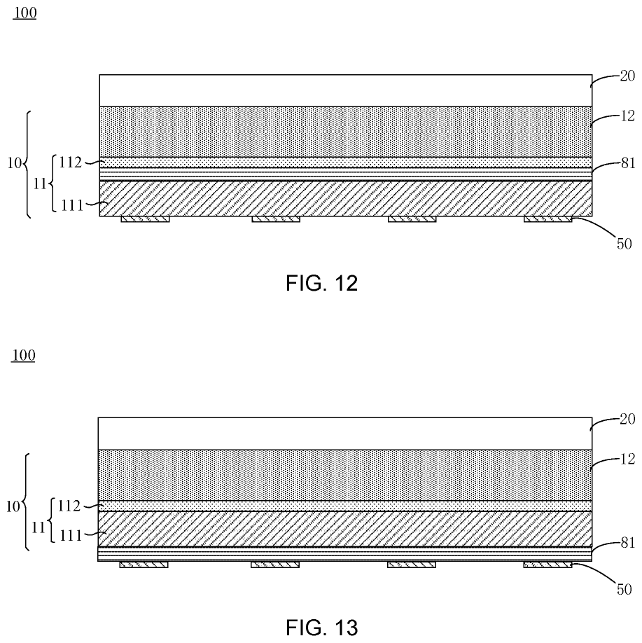

In some embodiments, as shown in FIG. 12 to FIG. 14, the protective layer 80 includes a reflective layer 81, and the reflective layer 81 is provided between the substrate 111 and the trace layer 12 and/or between the substrate 111 and the plurality of second electrodes 50.

In some examples, as shown in FIG. 12, the protective layer 80 may be a reflective layer 81, and the reflective layer 81 is provided between the substrate 111 and the trace layer 12.

When the plurality of side traces 40 are processed using a laser light etching process, a portion of the laser light penetrates through the substrate 111, and is incident to the trace layer 12. The reflective layer 81 is located between the substrate 111 and the trace layer 12, and the reflective layer 81 can reflect the portion of the laser light penetrating through the substrate 111 to prevent the portion of the laser light penetrating through the substrate 111 from being incident to the trace layer 12, thereby achieving the purpose of protecting the trace layer 12.

In some other examples, as shown in FIG. 13, the protective layer 80 may be a reflective layer 81, and the reflective layer 81 is provided between the substrate 111 and the plurality of second electrodes 50.

When the plurality of side traces 40 are processed using a laser light etching process, the laser light penetrates through gaps between the side traces 40, and is incident to the reflective layer 81. The reflective layer 81 is located between the substrate 111 and the plurality of second electrodes 50, and the reflective layer 81 can reflect a portion of the laser light. That is to say, the portion of the laser light cannot penetrate the substrate 111 and will not be incident to the trace layer, thereby achieving the purpose of protecting the trace layer 12.

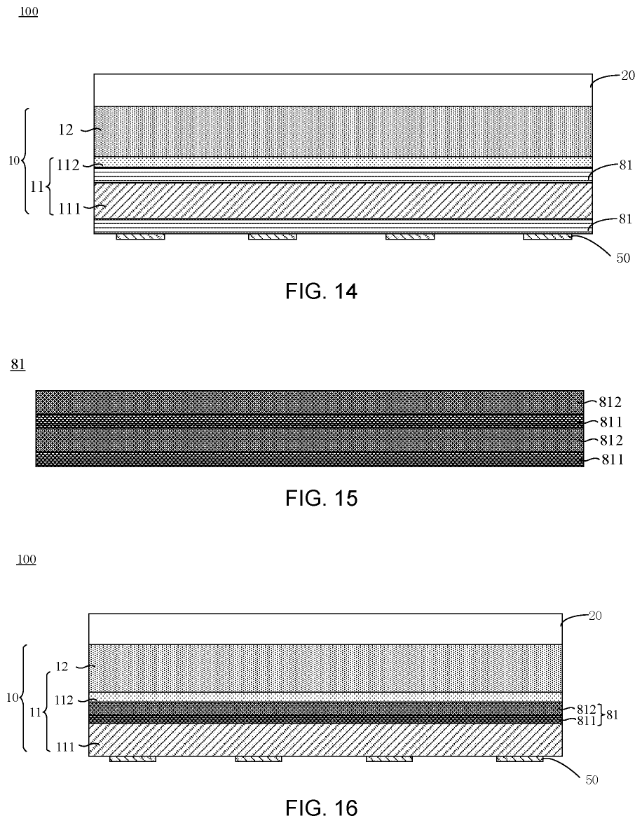

In yet some other examples, as shown in FIG. 14, the protective layer 80 may be a reflective layer 81. The substrate 111 and the trace layer 12, and the substrate 111 and the plurality of second electrodes 50 are both provided therebetween with the reflective layer 81.

When the plurality of side traces 40 are processed by a laser light etching process, the laser light penetrates through gaps between the side traces 40 is incident to a reflective layer 81 located between the substrate 111 and the plurality of second electrodes 50. The reflective layer 81 can reflect a portion of the laser light. A small portion of the remaining laser light penetrates through the substrate 111, and is incident to a reflective layer 81 between the substrate 111 and the trace layer 12, and the small portion of the remaining laser light can be further reflected, so that the energy of the laser light incident to the trace layer 12 is relatively small, and the trace layer does not suffer from the breakage of the traces or change in the characteristics of the active layer as a result.

In some embodiments, as shown in FIG. 15, the reflective layer 81 includes at least two film layers stacked in a stack, in which the reflective layer 81 includes two materials with different refractive indexes.

In some embodiments, the two materials with different refractive indexes include a first material, the first material is titanium dioxide, and a film layer formed by the first material is provided between the base and a film layer formed by the second material.

In some embodiments, the second material is silicon dioxide.

In some examples, the reflective layer 81 includes at least two film layers, and the at least two film layers are stacked in sequence. Two adjacent film layers are made of materials with different refractive indexes. The at least two film layers may improve the reflectivity of the laser light for a specific wavelength.

The reflective layer 81 includes at least two film layers: a first film layer 811 and a second film layer 812. The first film layer 811 is made of a first material. For example, the first film layer 811 may be made of titanium dioxide, and the refractive index of the first film layer 811 is 2.55. The second film layer 812 is made of a second material. For example, the second film layer 812 may be made of silicon dioxide, and the refractive index of the second film layer 812 is 1.45.

In some examples, a reflective layer 81 is provided between the substrate 111 and the trace layer 12. Exemplarily, as shown in FIG. 16, the reflective layer 81 includes a first film layer 811 and a second film layer 812 located on a side of the first film layer 811 away from the substrate 111. The first film layer 811 is provided on a side of the substrate 111 proximate to the trace layer 12, and the trace layer 12 is provided on a side of the second film layer 812 away from the substrate 111. A portion of the laser light that penetrates through the substrate 111 is reflected after being incident to the first film layer 811 and the second film layer 812, preventing the portion of the laser light from directly being incident to the trace layer 12, which may avoid problems such as the breakage of a certain connection trace or the shift in the threshold voltage of a certain thin film transistor, improving the product yield.

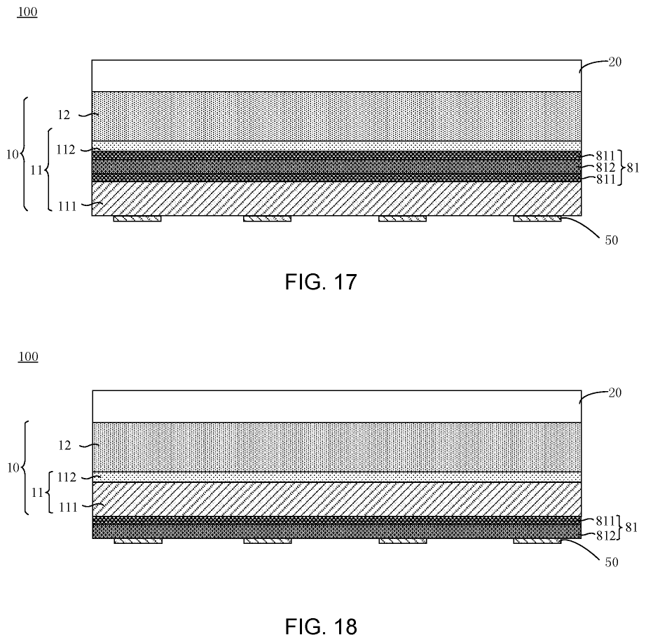

Alternatively, as shown in FIG. 17, the reflective layer 81 may include three film layers: two first film layers 811 and one second film layer 812 located between the two first film layers 811. The 1^{st} first film layer 811 is provided on a side of the substrate 111 proximate to the trace layer 12, the 2^{nd} first film layer 812 is provided on a side of the 1^{st} first film layer 811 away from the substrate 111, and the 2^{nd} first film layer 811 is provided on a side of the second film layer 812 away from the substrate 111, and the trace layer 12 is provided on a side of the 2^{nd} first film layer 811 away from the substrate 111. Here, the first film layers 811 may be made of titanium dioxide, and the second film layer 812 may be made of silicon dioxide. A portion of the laser light that penetrates through the substrate 111 is incident to the 1^{st} first film layer 811, the second film layer 812 and the 2^{nd} first film layer 811, and can be reflected between interfaces of every two adjacent film layers, preventing the laser light from directly being incident to the trace layer, which may avoid problems such as the breakage of a certain connection trace or the shift in the threshold voltage of a certain thin film transistor, improving the product yield.

In some other examples, a reflective layer 81 is provided between the substrate 111 and the plurality of second electrodes 50. Exemplarily, as shown in FIG. 18, the reflective layer 81 includes a first film layer 811 and a second film layer 812. Among them, the first film layer 811 is provided on a side of the substrate 111 away from the trace layer 12, the second film layer 812 is provided on a side of the first film layer 811 away from the substrate 111, and the plurality of second electrodes 50 are provided on a side of the second film layer 812 away from the substrate 111. When etching side traces, a portion of the laser light penetrates through a gap between two adjacent side traces, and is incident to the first film layer 811 and the second film layer 812, and then is reflected by the first film layer 811 and the second film layer 812, preventing the laser light from directly being incident to the trace layer 12, which may avoid problems such as the breakage of a certain connection trace or the shift in the threshold voltage of a certain thin film transistor, improving the product yield.

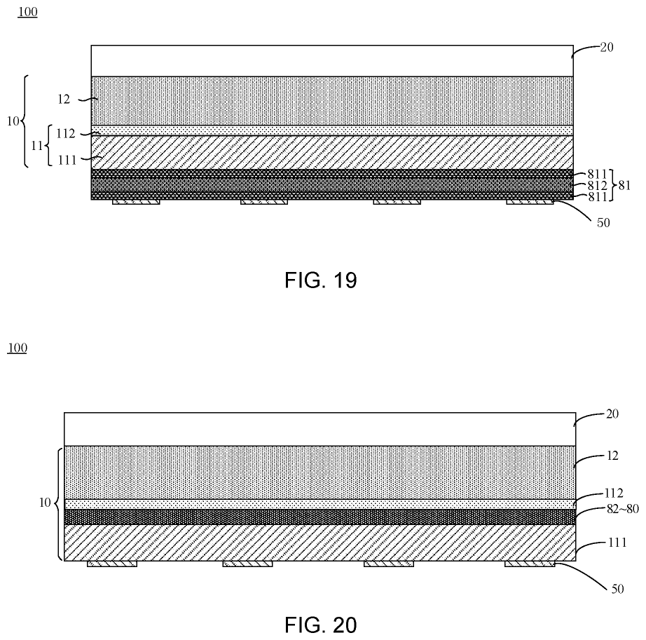

Alternatively, as shown in FIG. 19, the reflective layer 81 may include three film layers: two first film layers 811 and one second film layer 812 located between the two first film layers 811. The 1^{st} first film layer 811 is provided on a side of the substrate 111, the second first film layer 812 is provided on a side of the 1^{st} first film layer 811 away from the substrate 111, and the 2^{nd} first film layer 811 is provided on a side of the second film layer away from the substrate 111, and the plurality of second electrodes 50 is provided on a side of the second first film layer 811 away from the substrate 111. Here, the first film layers 811 may be made of titanium dioxide. A portion of the laser light that penetrates through the substrate 111 is incident to the 1^{st} first film layer 811, the second film layer 812 and the 2^{nd} first film layer 811, and can be reflected between interfaces of every two adjacent film layers, preventing the laser light from directly being incident to the trace layer, which may avoid problems such as the breakage of a certain connection trace or the shift in the threshold voltage of a certain thin film transistor, improving the product yield.

It can be understood that the reflective layer may also include four film layers, five film layers, or more film layers. A first film layer 811 is provided on a side of the substrate 111 proximate to the trace layer 12, or provided on a side of the substrate 111 away from the trace layer 12. The first film layer is made of titanium dioxide, a second film layer is made of silicon dioxide, a third film layer is made of titanium dioxide, and so on. That is, materials of two adjacent film layers are titanium dioxide and silicon dioxide, respectively.

In some embodiments, a wavelength of the laser light to be reflected by the reflective layer is A, and a product of a thickness d1 of a film layer formed by the first material and a refractive index of the first material is ¼ times the wavelength of the light to be reflected.

In some examples, the first material is titanium dioxide. The refractive index n1 of titanium dioxide is 2.55. The wavelength of the laser light to be reflected by the reflective layer is λ. In the embodiments of the present disclosure, the wavelength A of the laser light used for etching is 355 nm. In order to achieve a total reflection of the laser light with the wavelength of λ, a thickness of a film layer using titanium dioxide is used as d1, where:

$$d 1 = \frac{λ}{4 n 1} .$$

It can be known that the thickness of the film layer using titanium dioxide is 35.3 nm. That is to say, a thickness of each of the odd-numbered film layers, such as the first film layer, the third film layer and the fifth film layer, is 35.3 nm.

In some embodiments, a product of a thickness d2 of a film layer formed by the second material and a refractive index of the second material is ¼ times the wavelength of the light to be reflected.

In some examples, the second material is silicon dioxide. The refractive index n2 of silicon dioxide is 1.45. The wavelength of the laser light to be reflected by the reflective layer is λ. In the embodiments of the present disclosure, the wavelength λ of the laser light used for etching is 355 nm. In order to achieve total a reflection of the laser light with the wavelength of λ, a thickness of a film layer using silicon dioxide is used as d2, where:

$$d 2 = \frac{λ}{4 n 2} .$$

It can be known that the thickness of the film layer using silicon dioxide is 59.2 nm. That is to say, a thickness of each of the even-numbered film layers, such as the second film layer and the fourth film layer, is 59.2 nm.

The first material is titanium dioxide, and the thickness of the film layer formed by the first material is 35.3 nm. The second material is silicon dioxide, and the thickness of the film layer formed by the second material is 59.2 nm. The thicknesses of the corresponding film layers of different materials can cause total reflection of the laser light having the wavelength λ of 355 nm. This is to say, the thickness of the film layer described above has a high reflection efficiency for the laser light having the wavelength λ of 355 nm.

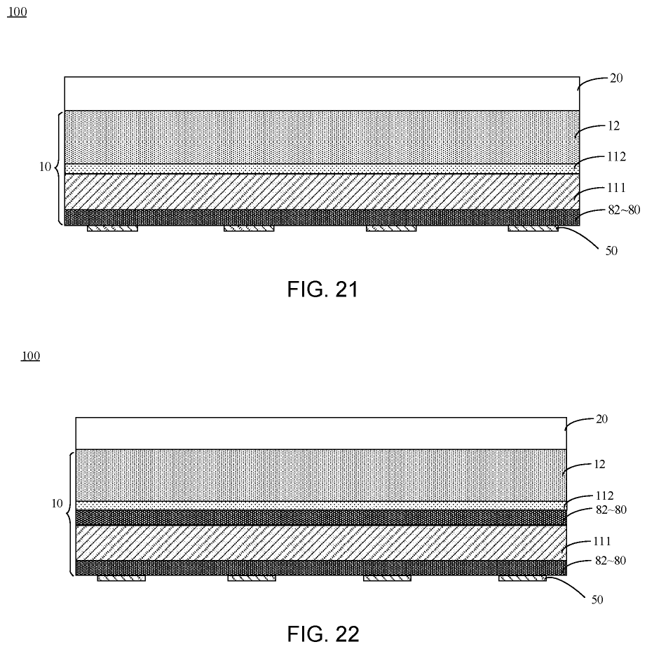

In some embodiments, as shown in FIG. 20, FIG. 21 and FIG. 22, the protective layer 80 includes an energy absorbing layer 82. The energy absorbing layer 82 is provided between the substrate 111 and the trace layer 12 and/or between the substrate 111 and the plurality of second electrodes 50.

In the first example, as shown in FIG. 20, the protective layer 80 includes an energy absorbing layer 82, and the energy absorbing layer 82 is provided between the substrate 111 and the trace layer 12. Exemplarily, the energy absorbing layer 82 is provided on a side of the substrate 111 proximate to the trace layer 12, the buffer layer 112 is provided on a side of the energy absorbing layer 82 away from the substrate 111, and the trace layer 12 is provided on a side of the buffer layer 112 away from the substrate 111.

In the second example, as shown in FIG. 21, the protective layer 80 includes an energy absorbing layer 82, and the energy absorbing layer 82 is provided between the substrate 111 and the plurality of second electrodes 50. Exemplarily, the energy absorbing layer 82 is provided on a side of the substrate 111 away from the trace layer 12, and the plurality of second electrodes 50 are provided on a side of the energy absorbing layer 82 away from the substrate 111.

In the third example, as shown in FIG. 22, the protective layer 80 includes an energy absorbing layer 82. the substrate 111 and the trace layer 12, and the substrate 111 and the plurality of second electrodes 50 are both provided therebetween with the energy absorbing layer 82. Exemplarily, an energy absorbing layer 82 is provided on a side of the substrate 111 proximate to the trace layer 12, the buffer layer 112 is provided on a side of the energy absorbing layer 82 away from the substrate 111, and the trace layer 12 is provided on a side of the buffer layer 112 away from the substrate 111. Furthermore, another energy absorbing layer 82 is provided on a side of the substrate 111 away from the trace layer 12, and the plurality of second electrodes 50 are provided on a side of the another energy absorbing layer 82 away from the substrate 111.

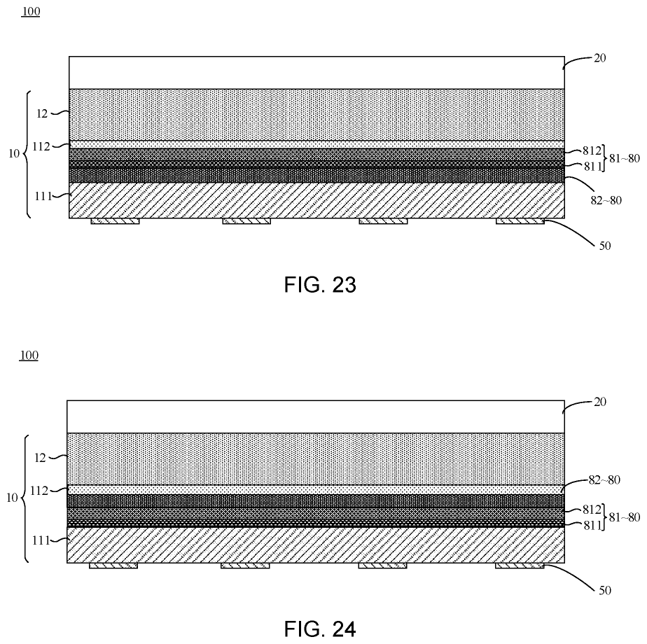

In the fourth example, as shown in FIG. 23 and FIG. 24, the protective layer 80 includes a reflective layer 81 and an energy absorbing layer 82, and the reflective layer and the energy absorbing layer are provided between the substrate 111 and the trace layer 12. Exemplarily, as shown in FIG. 23, the energy absorbing layer 82 is provided on a side of the substrate 111 proximate to the trace layer 12, the reflective layer 81 is provided on a side of the energy absorbing layer away from the substrate 111, and the trace layer 12 is provided on a side of the reflective layer 81 away from the substrate 111. Alternatively, as shown in FIG. 24, the reflective layer 81 is provided on a side of the substrate 111 proximate to the trace layer 12, the energy absorbing layer 82 is provided on a side of the reflective layer 81 away from the substrate 111, and the trace layer 12 is provided on a side of the energy absorbing layer 82 away from the substrate 111.

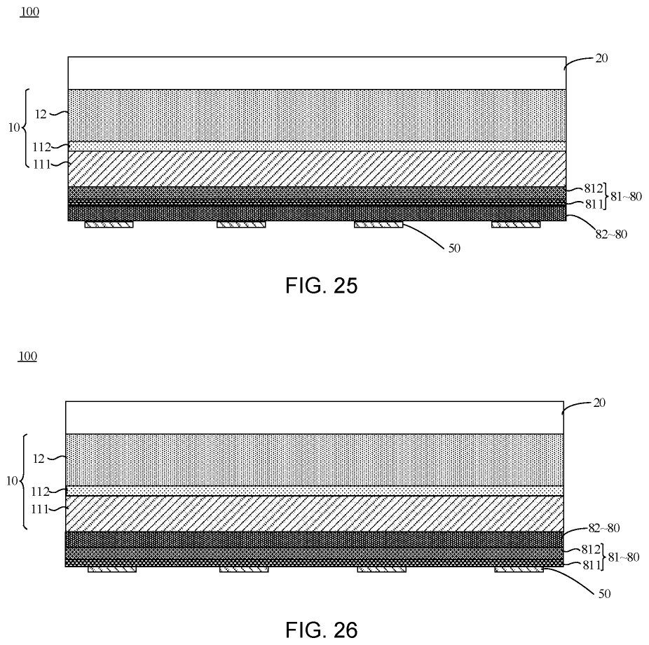

In the fifth example, as shown in FIG. 25 and FIG. 26, the protective layer 80 includes a reflective layer 81 and an energy absorbing layer 82, and the reflective layer 81 and the energy absorbing layer 82 are provided between the substrate 111 and the plurality of second electrodes 50. Exemplarily, as shown in FIG. 25, the energy absorbing layer 82 is provided on a side of the substrate 111 away from the trace layer 12, the reflective layer 81 is provided on a side of the energy absorbing layer 82 away from the substrate 111, and the plurality of second electrodes 50 are provided on a side of the reflective layer 81 away from the substrate 111. Alternatively, as shown in FIG. 26, the reflective layer 81 is provided on a side of the substrate 111 away from the trace layer 12, the energy absorbing layer 82 is provided on a side of the reflective layer 81 away from the substrate 111, and the plurality of second electrodes 50 are provided on a side of the energy absorbing layer 82 away from the substrate 111.

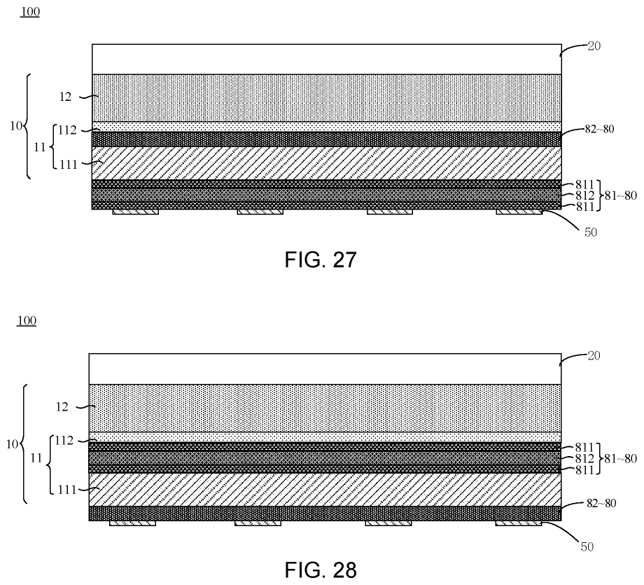

In the sixth example, as shown in FIG. 27, protective layers 80 include a reflective layer 81 and an energy absorbing layer 82. The energy absorbing layer 82 is provided between the substrate 111 and the trace layer 12, and the reflective layer 81 is provided between the substrate 111 and the second electrodes 50. Exemplarily, the energy absorbing layer 82 is provided on a side of the substrate 111 proximate to the trace layer 12, and the trace layer 12 is provided on a side of the energy absorbing layer 82 away from the substrate 111; and the reflective layer 81 is provided on a side of the substrate 111 away from the trace layer 12 81, and the plurality of second electrodes 50 are provided on a side of the reflective layer 81 away from the substrate 111.

In the seventh example, as shown in FIG. 28, protective layers 80 include a reflective layer 81 and an energy absorbing layer 82. The energy absorbing layer 82 is provided between the substrate 111 and the plurality of second electrodes 50, and the reflective layer 81 is provided between the substrate 111 and trace layer 12. Exemplarily, the energy absorbing layer 82 is provided on a side of the substrate 111 away from the trace layer 12, and the plurality of second electrodes 50 are provided on a side of the energy absorbing layer 82 away from the substrate 111; and the reflective layer 81 is provided on a side of the substrate 111 proximate to the trace layer 12, and the trace layer 12 is provided on a side of the reflective layer 81 away from the substrate 111.

It can be understood that the reflective layer 81 in the above-mentioned first example, second example, third example, fourth example, fifth example, sixth example and seventh film layer may include two film layers, three film layers, five film layers or more. The specific arrangement of the film layers will not be described in detail here.

In some embodiments, a material of the energy absorbing layer has a band gap less than 3.5 eV. Exemplarily, the wavelength λ of the laser light to be absorbed is 355 nm, and the photon energy of the laser light with the wavelength λ of 355 nm is 3.5 eV. In order to be able to absorb the energy of the laser light with a wavelength λ of 355 nm, the material of the energy absorbing layer has a band gap less than 3.5 eV.

In some embodiments, the material of the energy absorbing layer 82 is titanium dioxide. Exemplarily, titanium dioxide has a band gap Eg less than 3.2 eV, and the photon energy of the laser light with the wavelength λ of 355 nm is 3.5 eV, which is greater than the band gap Eg of titanium dioxide. Titanium dioxide is capable of absorbing the energy of the laser light with the wavelength λ of 355 nm, thus blocking the energy of the laser light from being transferred to the trace layer and preventing the laser light from adversely affecting the connection trace or the active layer.

Exemplarily, as shown in FIG. 20 to FIG. 28, the energy absorbing layer 82 is capable of absorbing the energy of the laser light with the wavelength λ of 355 nm. That is to say, when the laser light with the wavelength λ of 355 nm penetrates through the energy absorbing layer 82, the energy absorbing layer 82 can absorb the energy of the laser light, reducing the intensity of the laser light. After the laser light is incident to the trace layer, the laser light with the low intensity may not cause damage to the connection traces or the active layer in the trace layer 12. Of course, combined with the reflective layer 81, the laser light can be further reflected, so the intensity of the laser light incident to the trace layer 12 may be negligible.

In another aspect, as shown in FIG. 8 to FIG. 28, some embodiments of the present disclosure provide a display panel 100. The display panel 100 includes: a plurality of light-emitting devices and the array substrate 10 as described in any of the above embodiments. The array substrate 10 includes the substrate 111 and the trace layer provided on the substrate 111. Among them, the plurality of light-emitting devices are arranged in an array on a side of the trace layer 12 away from the substrate 111, and the trace layer 12 is electrically connected to the plurality of light-emitting devices.

In some examples, the display panel includes a protective layer 80, and the protective layer 80 may include a reflective layer 81 and/or an energy absorbing layer 82. Therefore, the display panel has the same beneficial effects as the above-mentioned array substrate, which will not be described again here.

In yet another aspect, some embodiments of the present disclosure provide a display device. The display device includes a driving circuit board and the display panel as described in the above embodiments. The display panel includes the substrate and the trace layer provided on the substrate. The plurality of second electrodes are provided on a side of the substrate away from the trace layer. Among them, the driving circuit board is provided on a side of the substrate away from the trace layer, and the driving circuit board may be electrically connected to the plurality of second electrodes through a flexible circuit board.

Since the display device adopts the display panel provided in the above embodiments, it has the same beneficial effect as the display panel and will not be described herein.

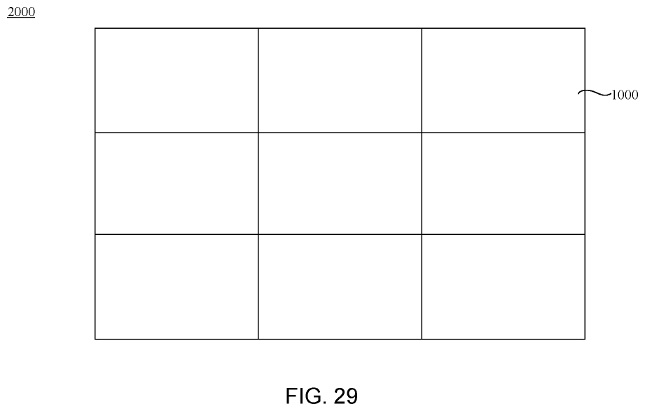

In yet another aspect, as shown in FIG. 29, some embodiments of the present disclosure provide a tiled display apparatus 2000. The tiled display apparatus includes a plurality of display devices 1000 each as described in the above embodiments. The plurality of display devices 1000 are tiled together.

Since the tiled display apparatus 2000 provided in the embodiments adopts the display device 1000 provided in the above embodiment, it has the same beneficial effect as the display device 1000 and will not be described herein.

The foregoing descriptions are merely specific implementations of the present disclosure, but the protection scope of the present disclosure is not limited thereto. Any changes or replacements that a person skilled in the art could readily conceive of within the technical scope of the present disclosure shall be included in the protection scope of the present disclosure. Therefore, the protection scope of the present disclosure shall be subject to the protection scope of the claims.

1. An array substrate, comprising:
a substrate;
a trace layer, provided on the substrate;
a plurality of second electrodes, provided on a side of the substrate away from the trace layer, wherein the trace layer is electrically connected to the plurality of second electrodes; and
a protective layer, provided between the substrate and the trace layer, and/or another protective layer, provided between the substrate and the plurality of second electrodes.

2. The array substrate according to claim 1, wherein at least one protective layer includes a reflective layer.

3. The array substrate according to claim 2, wherein the reflective layer includes at least two film layers provided in a stack;
wherein the reflective layer includes two materials with different refractive indexes, and materials of two adjacent film layers are different.

4. The array substrate according to claim 3, wherein the two materials with different refractive indexes include a first material; and
a product of a thickness of a film layer formed by the first material and a refractive index of the first material is ¼ times a wavelength of light to be reflected by the reflective layer.

5. The array substrate according to claim 3, wherein the two materials with different refractive indexes include a second material; and
a product of a thickness of a film layer formed by the second material and a refractive index of the second material is ¼ times a wavelength of light to be reflected by the reflective layer.

6. The array substrate according to claim 5, wherein the two materials with different refractive indexes include a first material, the first material is titanium dioxide, and a film layer formed by the first material is provided on the substrate.

7. The array substrate according to claim 5, wherein the second material is silicon dioxide.

8. The array substrate according to claim 1, wherein at least one protective layer includes an energy absorbing layer.

9. The array substrate according to claim 8, wherein the energy absorbing layer has a band gap less than 3.5 eV.

10. The array substrate according to claim 9, wherein a material of the energy absorbing layer is titanium dioxide.

11. The array substrate according to claim 1, wherein the trace layer includes a plurality of connection traces, and the plurality of connection traces are electrically connected to the plurality of second electrodes; and
an orthographic projection of the plurality of connection traces on the substrate is located within an orthographic projection of at least one protective layer on the substrate.

12. The array substrate according to claim 1, wherein the trace layer includes a driving circuit layer, and the driving circuit layer includes:
an active layer, provided on the substrate or the protective layer provided between the substrate and trace layer; and
a gate layer, provided on a side of the active layer away from the substrate;
wherein an orthographic projection of the active layer on the substrate is located within an orthographic projection of at least one protective layer on the substrate.

13. A display panel, comprising:
the array substrate according to claim 1, further including a driving circuit layer provided on the substrate; and
a plurality of light-emitting devices, arranged in an array on a side of the driving circuit layer away from the substrate.

14. A display device, comprising:
the display panel according to claim 13;
a flexible circuit board; and
a driving circuit board, provided on a side of the substrate away from the trace layer, wherein the driving circuit board is electrically connected to the trace layer through the flexible circuit board.

15. A tiled display apparatus, comprising a plurality of display devices each according to claim 14, wherein the plurality of display devices are tiled together.

16. The array substrate according to claim 1, wherein
the protective layer provided between the substrate and the trace layer includes an energy absorbing layer, and the another protective layer provided between the substrate and the plurality of second electrodes includes a reflective layer; or
the protective layer provided between the substrate and the trace layer includes a reflective layer, and the another protective layer provided between the substrate and the plurality of second electrodes includes an energy absorbing layer.

17. The array substrate according to claim 3, wherein the two materials with different refractive indexes include a first material and a second material, wherein
a film layer formed by the first material is provided between the substrate and a film layer formed by the second material; and
a refractive index of the first material is greater than a refractive index of the second material.

18. The array substrate according to claim 3, wherein the two materials with different refractive indexes include a first material and a second material, wherein
the first material forms at least one first film layer, the second material forms at least one second film layer, and the at least one first film layer are alternately arranged with the at least one second film layer; and in the reflective layer, a film layer closest to the substrate is a first film layer; and
a refractive index of the first material is greater than a refractive index of the second material.

19. The array substrate according to claim 6, wherein the film layer formed by the first material is located between the substrate and a film layer formed by the second material.
